(19) United States
(12) Patent Application Publication
(10) Pub. No.: US 2024/0412485 A1
(43) Pub. Date: Dec. 12, 2024

(54) METHOD AND SYSTEM FOR POINT CLOUD PROCESSING AND VIEWING

(71) Applicant: Siemens-Industry-Software-Ltd., Tel Aviv (IL)

(72) Inventors: Ahmed Agbaryah, Jish (IL); Rafael Blumenfeld, Raanana (IL)

(21) Appl. No.: 18/700,290

(22) PCT Filed: Nov. 11, 2021
(86) PCT No.: PCT/IB2021/060439

§ 371 Date: Apr. 11, 2024

(51) Int. Cl. G06V 10/771; G06V 20/64

(52) U.S. Cl. CPC G06V 10/771; G06V 20/64

(57) ABSTRACT

A system and a method for processing and filtering a point cloud. After acquiring or receiving a point cloud representing a scene with one or several objects, an object detection algorithm is used for detecting the objects. The ODA outputs, for each detected object, an object type and an associated bounding box list. Each bounding box defines a spatial location within the point cloud that has a set of points representing the object or a part thereof. For each of the predefined object types, a first list of all bounding boxes is created that were outputted together with the predefined type. For each bounding box outputted by the ODA, a second list is created of all predefined object types that were outputted for a detected object whose bounding box list has that bounding box. At least one of the created lists is used for automatically filtering the point cloud.

### TECHNICAL FIELD

The present disclosure is directed, in general, to computer-aided design, visualization, and manufacturing (“CAD”) systems, product lifecycle management (“PLM”) systems, product data management (“PDM”) systems, production environment simulation, and similar systems, that manage data for products and other items (collectively, “Product Data Management” systems or PDM systems). More specifically, the disclosure is directed to production environment simulation.

### BACKGROUND OF THE DISCLOSURE

In manufacturing plant design, three-dimensional (“3D”) digital models of manufacturing assets are used for a variety of manufacturing planning purposes. Examples of such usages includes, but are not limited by, manufacturing process analysis, manufacturing process simulation, equipment collision checks and virtual commissioning.

As used herein the terms manufacturing assets and devices denote any resource, machinery, part and/or any other object present in the manufacturing lines.

Manufacturing process planners use digital solutions to plan, validate and optimize production lines before building the lines, to minimize errors and shorten commissioning time.

Process planners are typically required during the phase of 3D digital modeling of the assets of the plant lines.

While digitally planning the production processes of manufacturing lines, the manufacturing simulation planners need to insert into the virtual scene a large variety of devices that are part of the production lines. Examples of plant devices include, but are not limited by, industrial robots and their tools, transportation assets like e.g. conveyors, turn tables, safety assets like e.g. fences, gates, automation assets like e.g. clamps, grippers, fixtures that grasp parts and more.

In such a context, the point cloud, i.e. the digital representation of a physical object or environment by a set of data points in space, became more and more relevant for applications in the industrial world. Indeed, the acquisition of point clouds with 3D scanners enables for instance to rapidly get a 3D image of a scene, e.g. of a production line of a shop floor, said 3D image being more correct (in terms of content) and up to date compared to designing the same scene using 3D tools. This ability of the point cloud technology to rapidly provide a current and correct representation of an object of interest is of great interest for decision taking and task planning since it shows the very latest and exact status of the shop floor.

Unfortunately, one of the drawbacks of the point cloud technology is that a point cloud viewer will load the entire point cloud data so that an end-user will always see the complete 3D representation of a scene, with all relevant information and objects, but also with all irrelevant information and objects. In other words, it is not possible at the moment to filter the scene for representing only the relevant objects and information.

Of course, manual processes exist for displaying a set of points representing a specific object of a scene. But this means that a user has to manually select irrelevant points of the cloud and hide them from the scene so that only relevant points representing said specific object remain. Such a manual selection is a very time-consuming task which is furthermore prone to human errors.

Therefore, improved techniques for viewing point clouds are desirable.

### SUMMARY OF THE DISCLOSURE

Various disclosed embodiments include methods, systems, and computer readable mediums for processing a point cloud representing a scene, and providing notably an automatic filtering of point cloud data enabling to display only, or hide only, one or several sets of points of said point cloud, wherein each set of points represents an object of said scene belonging to a predefined type of objects or a part of said object. A method includes acquiring or receiving, for instance via a first interface, a point cloud representing a scene, wherein said scene comprises one or several objects; using an Object Detection Algorithm (hereafter “ODA”) for detecting said one or several objects (i.e. their representation) in said point cloud, the ODA being configured for outputting, for each object detected in the point cloud, an object type and a bounding box (hereafter “bbox”) list, wherein the object type belongs to a set of one or several predefined object types that the ODA has been trained to identify, and wherein each bbox of the bbox list defines a spatial location within the point cloud that comprises a set of points representing said object or a part of the latter. The ODA is notably configured for receiving as input said point cloud, for identifying within said point cloud one or several of said sets of points (or clusters of points), wherein each set of points defines thus a volume (i.e. a specific spatial distribution and/or configuration of points) that represents one of said objects, or a part of the latter, that the ODA has been trained to recognize or identify, i.e. objects that belong to one of the predefined object types (in particular, each set of points defines the external surface or boundary of a volume that represents the shape of said object or of a part of the latter). The ODA is thus configured for detecting said one or several objects in the point cloud from the identified sets of points, wherein each of said identified sets of points is associated to a bbox describing the spatial location of the concerned set of points, the ODA being further configured for outputting, for each object detected, an object type and a bbox list comprising all the bboxes that are each associated to a set of points identified as belonging (i.e. being part of) the detected object. In particular, the ODA is notably configured for combining several sets of points (resulting thus in a combination of corresponding bboxes) in order to detect one of said object and assign to the latter said type of object, wherein the object type is chosen among said set of one or several predefined object types. The bbox is typically configured for surrounding the points of the identified set of points, being usually rectangular with its position defined by the position of its corners; for each of the predefined object types that was outputted, automatically creating a first list of all bboxes that have been outputted together with said predefined type (said first list is notably the union of all bbox lists that have been outputted together with the same predefined type of object); for each bbox outputted by the ODA, automatically creating a second list of all predefined object types that have been outputted for a detected object for which the bbox list comprised said bbox; using at least one of the created lists, i.e. bbox list and/or first list and/or second list, for automatically filtering said point cloud. The filtered point cloud might be provided then, e.g. via a second interface, for further processing, for instance for visualization on a screen. For instance, said lists can be used for applying a filter to an image created from said point cloud. Preferentially, the method comprises also displaying, notably by means of a point cloud viewer, a resulting filtered point cloud and/or said filtered image of said scene, wherein, preferably, detected objects have been automatically hidden or wherein only the detected objects are displayed, i.e. wherein points in said point cloud that belong to the detected object, or resp. image parts in said image that belong to the detected object, have been automatically hidden in said point cloud, or resp. image, or wherein only said points, resp. parts, are displayed in said point cloud, resp. image.

A data processing system comprising a processor and an accessible memory or database is also disclosed, wherein the data processing system is configured to carry out the previously described method.

The present invention proposes also a non-transitory computer-readable medium encoded with executable instructions that, when executed, cause one or more data processing systems to perform the previously described method.

An example of computer-implemented method for providing, by a data processing system, a trained algorithm for detecting one or several objects in a point cloud representing a scene comprising said one or several objects and assigning, to each detected object, an object type chosen among a set of one or several predefined types and a list of one or several sets of points and/or a bbox list is also proposed by the present invention. This computer-implemented method comprises:
receiving input training data, wherein the input training data comprise a plurality of point clouds, each representing a scene, preferentially a different scene, each scene comprising one or several objects;
receiving output training data, wherein, for each point cloud received as input, the output training data comprise for, and associate to, at least one, preferentially each, object of the scene, a type of object chosen among said set of one or several predefined types and a list of bboxes, wherein each bbox of the bbox list defines a spatial location within said point cloud comprising a set of points representing said object or a part of the latter. In other words, said list of bboxes maps a list of one or several sets of points of the point cloud representing said scene, wherein each set of points defines a cluster of points that represents said object or a part of the latter (e.g. an arm of a robot), assigning thus to each of said clusters of points at least one type of objects (e.g. a cluster representing the arm of the robot might belong to the type “arm” and to the type “robot”). The output training data is thus configured for defining for, or assigning to, each of said sets of points, a bbox configured for describing the spatial location of the concerned set of points with respect to the point cloud (i.e. with a point cloud coordinate system), assigning thus to each object of the scene, an object type and a list of bbox corresponding to said list of one or several sets of points;
training an algorithm based on the input training data and the output training data;
providing the resulting trained algorithm.

The foregoing has outlined rather broadly the features and technical advantages of the present disclosure so that those skilled in the art may better understand the detailed description that follows. Additional features and advantages of the disclosure will be described hereinafter that form the subject of the claims. Those skilled in the art will appreciate that they may readily use the conception and the specific embodiment disclosed as a basis for modifying or designing other structures for carrying out the same purposes of the present disclosure. Those skilled in the art will also realize that such equivalent constructions do not depart from the spirit and scope of the disclosure in its broadest form.

Before undertaking the DETAILED DESCRIPTION below, it may be advantageous to set forth definitions of certain words or phrases used throughout this patent document: the terms “include” and “comprise,” as well as derivatives thereof, mean inclusion without limitation; the term “or” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, whether such a device is implemented in hardware, firmware, software or some combination of at least two of the same. It should be noted that the functionality associated with any particular controller may be centralized or distributed, whether locally or remotely. Definitions for certain words and phrases are provided throughout this patent document, and those of ordinary skill in the art will understand that such definitions apply in many, if not most, instances to prior as well as future uses of such defined words and phrases. While some terms may include a wide variety of embodiments, the appended claims may expressly limit these terms to specific embodiments.

### BRIEF DESCRIPTION OF THE DRAWINGS

For a more complete understanding of the present disclosure, and the advantages thereof, reference is now made to the following descriptions taken in conjunction with the accompanying drawings, wherein like numbers designate like objects, and in which:

FIG. 1 illustrates a block diagram of a data processing system in which an embodiment can be implemented.

FIG. 2 illustrates a flowchart describing a preferred embodiment of a method for automatically filtering images created from a point cloud according to the invention.

FIG. 3 schematically illustrates a point cloud according to the invention.

### DETAILED DESCRIPTION

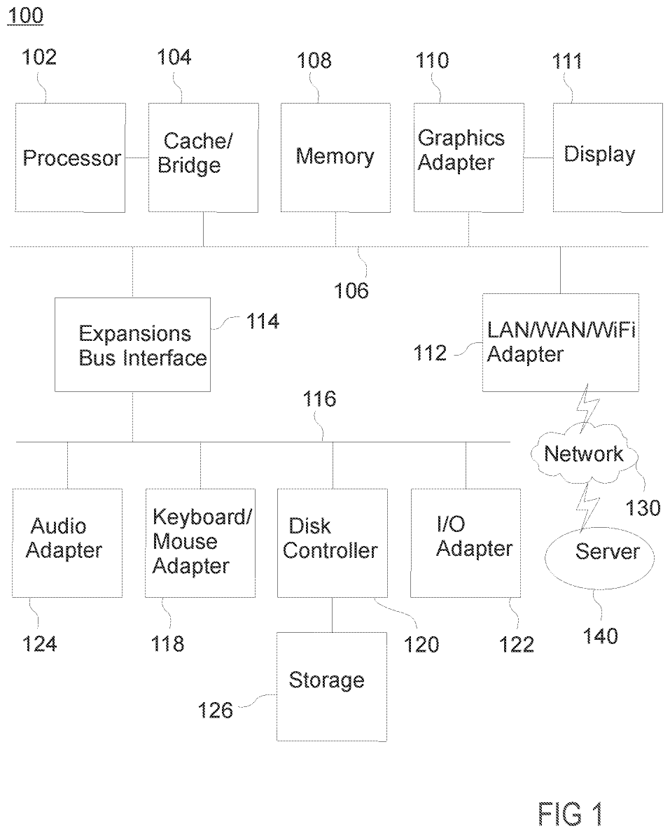

FIGS. 1 through 3, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged device. The numerous innovative teachings of the present application will be described with reference to exemplary non-limiting embodiments.

Current techniques for viewing point cloud do not offer any efficient filtering on objects. In other words, a user cannot select for instance an object appearing in a scene and make all similar objects of the scene hide, or at the opposite make all objects that are dissimilar to said selected object hide, keeping thus only the objects similar to the selected object displayed. The present invention proposes an efficient method and system, e.g. a data processing system, for overcoming this drawback, enabling thus a user to quickly display or hide objects of a same type, i.e. said similar objects, in said point cloud and/or in an image created from said point cloud. Said image can be for instance a 2D or 3D image created from part or the whole point cloud.

FIG. 1 illustrates a block diagram of a data processing system 100 in which an embodiment can be implemented, for example as a PDM system particularly configured by software or otherwise to perform the processes as described herein, and in particular as each one of a plurality of interconnected and communicating systems as described herein. The data processing system 100 illustrated can include a processor 102 connected to a level two cache/bridge 104, which is connected in turn to a local system bus 106. Local system bus 106 may be, for example, a peripheral component interconnect (PCI) architecture bus. Also connected to local system bus in the illustrated example are a main memory 108 and a graphics adapter 110. The graphics adapter 110 may be connected to display 111.

Other peripherals, such as local area network (LAN)/Wide Area Network/Wireless (e.g. WiFi) adapter 112, may also be connected to local system bus 106. Expansion bus interface 114 connects local system bus 106 to input/output (I/O) bus 116. I/O bus 116 is connected to keyboard/mouse adapter 118, disk controller 120, and I/O adapter 122. Disk controller 120 can be connected to a storage 126, which can be any suitable machine usable or machine readable storage medium, including but are not limited to nonvolatile, hard-coded type mediums such as read only memories (ROMs) or erasable, electrically programmable read only memories (EEPROMs), magnetic tape storage, and user-recordable type mediums such as floppy disks, hard disk drives and compact disk read only memories (CD-ROMs) or digital versatile disks (DVDs), and other known optical, electrical, or magnetic storage devices.

Also connected to I/O bus 116 in the example shown is audio adapter 124, to which speakers (not shown) may be connected for playing sounds. Keyboard/mouse adapter 118 provides a connection for a pointing device (not shown), such as a mouse, trackball, trackpointer, touchscreen, etc.

Those of ordinary skill in the art will appreciate that the hardware illustrated in FIG. 1 may vary for particular implementations. For example, other peripheral devices, such as an optical disk drive and the like, also may be used in addition or in place of the hardware illustrated. The illustrated example is provided for the purpose of explanation only and is not meant to imply architectural limitations with respect to the present disclosure.

A data processing system in accordance with an embodiment of the present disclosure can include an operating system employing a graphical user interface. The operating system permits multiple display windows to be presented in the graphical user interface simultaneously, with each display window providing an interface to a different application or to a different instance of the same application. A cursor in the graphical user interface may be manipulated by a user through the pointing device. The position of the cursor may be changed and/or an event, such as clicking a mouse button, generated to actuate a desired response.

One of various commercial operating systems, such as a version of Microsoft Windows™, a product of Microsoft Corporation located in Redmond, Wash. may be employed if suitably modified. The operating system is modified or created in accordance with the present disclosure as described.

LAN/WAN/Wireless adapter 112 can be connected to a network 130 (not a part of data processing system 100), which can be any public or private data processing system network or combination of networks, as known to those of skill in the art, including the Internet. Data processing system 100 can communicate over network 130 with server system 140, which is also not part of data processing system 100, but can be implemented, for example, as a separate data processing system 100.

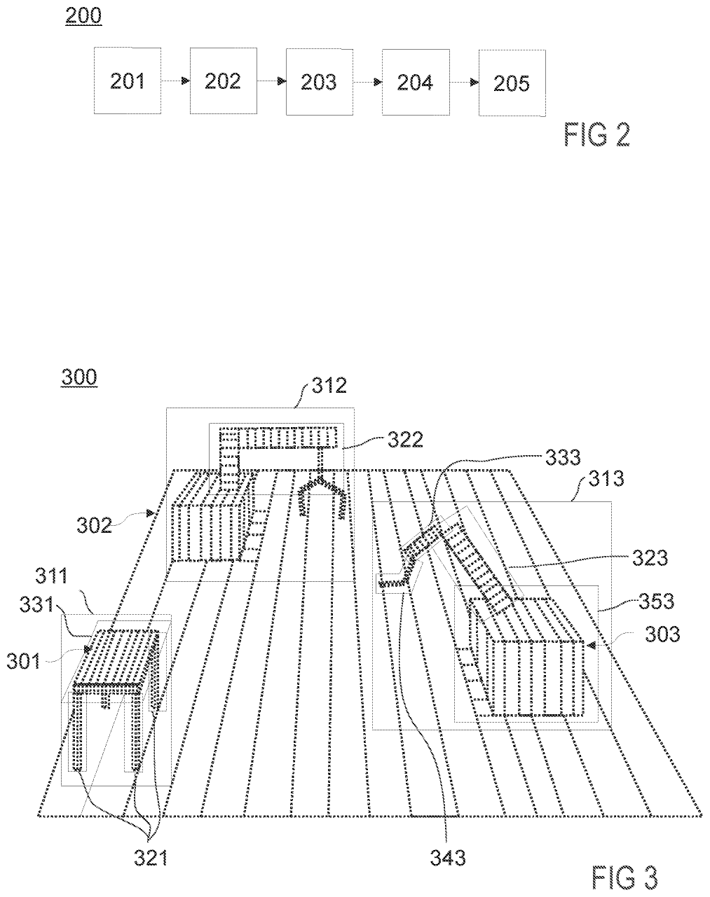

FIG. 2 illustrates a flowchart of a method for processing, filtering, and optionally viewing, a point cloud according to the invention. The method will be explained in details hereafter in connection with FIG. 3 which presents a schematic and non-limiting illustration of a point cloud 300 acquired for instance by a point cloud scanner, notably a 3D scanner, from a scene comprising a table 301, a first robot 302, and a second robot 303. As known in the art, the point cloud scanner is configured for scanning the scene, which is a real scene, e.g. a production line of a manufacture, and collecting, from said scanning, point cloud data, i.e. one or several sets of data points in space, wherein each point position is characterized by a set of position coordinates, and each point might further be characterized by a color. Said points represent the external surface of objects of the scene, and the scanner records thus within said point cloud data information about the position within said space of a multitude of points belonging to the external surfaces of objects surrounding the scanner, and can therefore reconstruct, from said point cloud data, 2D or 3D images of its surrounding environment, i.e. of said scene, for which the points have been collected. Of course, the present invention is not limited to this specific type of scanner, and might receive or acquire point cloud data from any other kind of scanner configured for outputting such point cloud data.

At step 201, the system according to the invention acquires or receives, for instance via a first interface, a point cloud 300 representing a scene comprising one or several objects, e.g. a table 301, a first robot 302, and a second robot 303. As known in the art, said points of the point cloud define the external surfaces of the objects of said scene, and thus the (external) shape of the objects. By acquiring or receiving a point cloud, it has to be understood that the system acquires or receives point cloud data. Said point cloud data can be received from a point cloud scanner, and/or from a database, and/or provided by an operator, etc. The point cloud data comprise a set of data points in a space, as known in the art when referring to point cloud technology. From said point cloud data, it is possible to reconstruct an image, e.g. a 2D or 3D image of the scene, notably using meshing techniques that enable to create object external surfaces from the points of the point cloud. FIG. 3 simply shows the points of the point cloud 300 in a Cartesian space. In other words, the points of the point cloud data can be represented in a Cartesian coordinate system or in any other adequate coordinate system. Optionally and additionally, the system according to the invention may acquire or receive one or several images (e.g. coplanar set of pixels) of said scene, wherein each image is preferentially created from said point cloud or point cloud data, for instance from said scanner that has been used for collecting the cloud of points by scanning said scene. Said images can be 2D or 3D representations of the scene. In particular, said images might have been obtained by applying a meshing technique to the point cloud in order to create external surfaces of the objects. Meshing techniques are known in the art and not the subject of the present invention.

At step 202, the system uses an Object Detection Algorithm—ODA—for detecting, in said point cloud, at least one of said one or several objects of the scene. The ODA is configured for outputting, for each detected object, an object type and a bbox list comprising one or several bbox, each bbox describing notably the spatial location, within said point cloud, of a set of points that represent said detected object or a part of the latter. The ODA is a trained algorithm, i.e. a machine learning (ML) algorithm, configured for receiving, as input, said point cloud and optionally said one or several images of the scene, and then for automatically detecting one or several objects in the received point cloud, using optionally said images as input, notably information comprised in said images, like RGB information, for improving the detection of said objects, and for outputting, for each object detected, said object type and the list of bbox. Advantageously, thanks to the reduced noise of said images compared to the point cloud noise, using said images together with the point cloud as input to the ODA improves the object detection by the ODA. In particular, the ODA might be configured for matching a received 2D or 3D image of the scene with the point cloud of said scene for acquiring additional or more precise information regarding the objects of said scene: typically, image information (e.g. color, surface information, etc.) that might be found at positions in said scene that correspond to positions of points of the point cloud might be used by the ODA for determining whether a specific point belongs or not to a detected object.

According to the present invention, the ODA has been trained for identifying, within the point cloud, sets of points whose spatial distribution and/or configuration, notably with respect to another set of points of said point cloud, matches the spatial distribution and/or configuration of sets of points representing objects of a scene that has been used for its training. Each set of points identified by the ODA represents thus an object or a part of an object that the ODA has been able to identify or recognize within the point cloud. The points of a set of points are usually spatially contiguous. The ODA is thus trained to identify or detect in said point cloud different sets of points that define volumes (in the sense of “shape”) that correspond, i.e. resemble, to volumes of object types it has been trained to detect. For instance, the ODA might have been trained to identify in point cloud data different types of robots and is able to recognize the different parts of the robot body. The training of the ODA enables thus the latter to efficiently identify some “predefined” spatial distributions and/or configurations of points within a point cloud and to assign to each set of points characterized by one of said “predefined” spatial distributions and/or configurations at least one type of object. The obtained different sets of points (or volumes), and notably how they combine together, enable the ODA to detect more complex objects, like a robot, that result from a combination of said different volumes (i.e. it enables the ODA to distinguish a first object type, e.g. “robot”, corresponding to a first combination of sets of points from a second object type, e.g. “table”, corresponding to a second combination of sets of points). Thus, the ODA might combine several of said identified sets of points for determining the type of object, the bbox list being then configured for listing the bboxes whose associated set of points is part of said combination. Indeed, and preferably, the ODA is configured for determining said type of object from the spatial configuration and interrelation of intersecting or overlapping (when considering the volume represented by each set) sets of points. For instance, a first volume or set of points might correspond to a rod (the rod might belong to the types “table leg”, “robot arm”, etc.), a second volume intersecting/overlapping with the first volume might correspond to a clamp (the clamp might belong to the types “robot”, “tools”, etc.), and a third volume intersecting/overlapping with the first volume might correspond to an actuator configured for moving the rod (the actuator might belong to the type “robot”, etc.), and due to the interrelation (respective orientation, size, etc.) and spatial configuration of the 3 volumes, the ODA is able to determine that the 3 volumes (i.e. sets of points) belong to an object of type “robot”. Furthermore, the ODA is preferentially configured for defining for, or assigning to, each set of points that has been identified, said bbox. The bbox defines an area or a volume within the point cloud that comprises the set of points it is assigned to. The ODA is thus configured for mapping each identified set of points to a bbox. Said bboxes are for instance rectangles as illustrated in FIG. 3 with the references 321, 331, 343, 333, 353, 323, or might have other shapes that are notably convenient for highlighting on a display a specific object or part of object. In particular, known in the art machine learning algorithms might be used for detecting said objects in said images for helping the ODA to determine sets of points corresponding to objects or object parts. At the end, as explained previously, the ODA is configured for outputting, for each detected object, a type of the object and a bbox list.

According to the present invention, the type of the object belongs to a set of one or several predefined types of objects that the ODA has been trained to detect or identify. For instance, referring back to FIG. 3, one type or class of object can be “robot”, wherein the first robot 302 and the second robot 303 belong to the same object type. The ODA might also be configured to identify different types of robots. According to FIG. 3, another type or category of object could be “table”. Based on FIG. 3, only object 301 is detected as belonging to the type “table”. The ODA can detect or identify a whole object and/or object parts. For instance, it is preferentially configured for detected object parts or elements, like the sets of points corresponding to each table leg 321, another set of points for the table top 331, other sets of points for the robot arms 323, 333 and for the robot clamp 343, etc. It is thus configured, i.e. trained, for identifying in a point cloud received as input, one or several sets of points corresponding to whole object or object parts it has been trained to identify or recognize. The ODA is typically configured for classifying each detected object (or object part), i.e. identified set of points, in one of said predefined types. In particular, a plurality of objects or object parts characterized by different shapes, edges, size, orientations, etc., might belong to a same object type. For instance, a round table, a coffee table, a rectangular table, etc., will all be classified in the same object class or type “table”. Then, since an object, e.g. a robot, might comprise different parts, e.g. a clamp, an arm, etc., then a type of object, e.g. the type “robot”, might be defined as a combinations of several objects (sub) types that have been trained to be detected or identified by the ODA. For instance, “table leg” and “table top” might be two (sub) types of objects that, when combined together, result in the object type “table”. The same applies for “robot arm”, which is a “sub-type” of the object type “robot”. By this way, the ODA may identify or detect in the point cloud a plurality of object types that represent simple shapes or volumes that are easily identifiable, and by combining the latter, it can determine the type of more complex objects.

The bbox according to the invention is configured for surrounding all points of said point cloud that are part of an identified set of points. FIG. 3 shows for instance bboxes 312, 322, 313, 323, 333, 343, 353 that have been determined by the ODA according to the invention. While shown as 2D rectangles, said bboxes have preferentially the same dimensions as the objects they surround, i.e. they will be 3D bboxes if the detected object is a 3D object. For the example of FIG. 3, the ODA is capable of distinguishing two different types of objects, namely the type “table” and the type “robot”. For instance, the ODA is configured for identifying the set of points comprised within the bboxes 353, 323, 333, and 343, to assign to each identified set of points a bbox, and to determine from the spatial distribution and/or configuration and/or interrelation (notably that they define intersecting/overlapping volumes) of said sets of points that their combination represents an object of type “robot”. The same applies to the set of points comprised within the bboxes 321 (i.e. table legs), and 301 (i.e. table top): from their spatial distribution and/or configuration and/or interrelation, the ODA will determine that they represent an object of type “table”. For each detected object, i.e. table, robot, arm, it outputs the object type and a bbox list comprising all bboxes that are related to the detected object in that they are each mapping a set of points that represents the detected object or a part of the latter. The object 301 is thus associated to the type “table” and surrounded by the bbox 311. The object 301 different parts, like table legs, might also be surrounded by bboxes 321. The first robot 302 and the second robot 303 are each associated to the type “robot” and surrounded respectively by the bbox 312 and 313. The arm of the first robot 302 is associated to the type “arm” and surrounded by the bbox 322. arm of the second robot 303 is associated to the type “arm” and surrounded by the bbox 323. If another robot arm would be placed on the table 301, then the ODA would associate it to the type “arm” and surround it with another bbox. Each bbox provides information about the location of the object with respect to the space where the point cloud is represented. At the end, the ODA outputs thus for each detected object a set of data comprising the object type and a bbox list, i.e. information about the object type and information about its size and position within the point cloud as provided by the bboxes of the list.

At step 203, for each of the predefined object types that was outputted by the ODA, the system according to the invention automatically creates a first list of all bboxes that have been outputted together with said predefined type of object. In other words, for the object type “table”, said first list will comprise the bboxes 311, 321, 331. For the object type “robot”, said first list will comprise the bboxes 313, 323, 333, 343, 353, 312, and 322. And finally, for the object type “arm”, the first list will comprise the bboxes 322, 333, and 323. It might also happen that the table legs (i.e. bbox 321) are comprised within the first list determined for the type “arm” due to a similar shape with robot arms. The bboxes are typically displayed on a user screen. Advantageously, said first list enables a quick filtering of the point cloud upon selection, e.g. by a user, of a predefined object type, for instance by clicking on one of the bboxes for the object type “robot”, or by selecting in a dropdown menu, the predefined type of object “robot”.

At step 204, which can take place simultaneously, after or before step 203, the system automatically creates, for each bbox outputted by the system, a second list, wherein said second list comprises all predefined object types that have been outputted for a detected object whose associated bbox list comprised said bbox. In other words, for each bounding box, the system according to the invention will list all predefined object types to which the bbox, and thus the set of points mapped or comprised within said bbox, belongs to. For instance, the second list defined for the bbox 323 will comprise the predefined object types “robot” and “arm”. The same applies to the second list defined for the bounding box 322. For the bounding box 311, the second list will only comprise the predefined object type “table. Advantageously, by selecting a bbox, a user can quickly get an overview of all types of objects that said bbox belongs to, making it possible to select one of said object types so that, for instance, the system only displays said type of object while all other objects are hidden.

At step 205, the system uses at least one of the created lists, e.g. the bbox list and/or the first list and/or the second list, for automatically filtering said point cloud. By filtering it has to be understood that for instance points belonging to all objects assigned or associated to a same object type can be hidden, i.e. are removed from said point cloud, or only said points are displayed, i.e. all other points are hidden. The system is notably configured for providing, e.g. via a second interface or via the first interface, the filtered point cloud. The filtered point cloud can be used then for different purposes. For instance, the system according to the invention can then display a resulting filtered image of said scene obtained from the filtered point cloud, wherein detected objects have been automatically hidden or wherein only the detected objects are displayed. For instance, upon a selection of a position within a displayed image of said scene that has been created from said point cloud, the system can automatically determine to which box said position belongs to, and then it can automatically display the second list associated to the bbox, i.e. the list of predefined object types to which said bbox belongs to. In particular, upon selection of one of the predefined object types of the second list, that can be for instance automatically displayed upon said selection of a position within the displayed image, only the set of points mapped by the bboxes listed in the first list created for the selected predefined object type are automatically displayed or hidden. Preferentially, even if the bbox defines a volume that comprises not only the detected object, but also part of the surrounding environment of said detected object, only the points of the set of points mapped to the bounding box are displayed, or resp. hidden. Advantageously, according to the present invention, a single detected object can be thus rapidly hidden, or only said detected object can be displayed by interaction with the bbox.

In embodiments, the term “receiving”, as used herein, can include retrieving from storage, receiving from another device or process, receiving via an interaction with a user or otherwise.

Those skilled in the art will recognize that, for simplicity and clarity, the full structure and operation of all data processing systems suitable for use with the present disclosure is not being illustrated or described herein. Instead, only so much of a data processing system as is unique to the present disclosure or necessary for an understanding of the present disclosure is illustrated and described. The remainder of the construction and operation of data processing system 100 may conform to any of the various current implementations and practices known in the art.

It is important to note that while the disclosure includes a description in the context of a fully functional system, those skilled in the art will appreciate that at least portions of the present disclosure are capable of being distributed in the form of instructions contained within a machine-usable, computer-usable, or computer-readable medium in any of a variety of forms, and that the present disclosure applies equally regardless of the particular type of instruction or signal bearing medium or storage medium utilized to actually carry out the distribution. Examples of machine usable/readable or computer usable/readable mediums include: nonvolatile, hard-coded type mediums such as read only memories (ROMs) or erasable, electrically programmable read only memories (EEPROMs), and user-recordable type mediums such as floppy disks, hard disk drives and compact disk read only memories (CD-ROMs) or digital versatile disks (DVDs).

Although an exemplary embodiment of the present disclosure has been described in detail, those skilled in the art will understand that various changes, substitutions, variations, and improvements disclosed herein may be made without departing from the spirit and scope of the disclosure in its broadest form.

None of the description in the present application should be read as implying that any particular element, step, or function is an essential element which must be included in the claim scope: the scope of patented subject matter is defined only by the allowed claims.

1-15. (canceled)

16. A method for processing a point cloud, the method comprising:
acquiring or receiving a point cloud representing a scene with one or several objects;
using an object detection algorithm for detecting the one or several objects in the point cloud, the ODA being configured for outputting, for each object detected in the point cloud, an object type and a list of bounding boxes (BBOX), wherein the object type is chosen from a set of one or several predefined object types that the ODA has been trained to identify, wherein each BBOX of the BBOX list defines a spatial location within the point cloud including a set of points representing the detected object or a part of the detected object;
for each of the predefined object types that was outputted, automatically creating a first list of all BBOXes that have been outputted together with the predefined type;
for each BBOX outputted by the ODA, automatically creating a second list of all predefined object types that have been outputted for a detected object whose associated BBOX list comprises the BBOX; and
using at least one of the first or second lists for automatically filtering the point cloud.

17. The method according to claim 16, which comprises, upon a selection of a position within a displayed image created from the point cloud, automatically determining to which BBOX the position belongs, and automatically displaying the second list of predefined object types listed for the respective BBOX.

18. The method according to claim 16, wherein, upon selection of one of the predefined object types of the second list of predefined object types, the filtering comprises automatically displaying or hiding only those points of the set or sets of points associated with the BBOXes of the first list created for the predefined object type that has been selected.

19. The method according to claim 16, further comprising providing the filtered point cloud via an interface.

20. The method according to claim 19, further comprising using the filtered point cloud for visualization on a screen.

21. The method according to claim 16, wherein the ODA is a trained algorithm configured for receiving, as input, a point cloud, and for automatically detecting or identifying one or several sets of points within the received point cloud matching at least one of a spatial configuration or distribution of objects or parts of objects that the ODA has been trained to detect, wherein each of the objects belongs to one of the predefined object types, for mapping each of the sets of points to a BBOX, and for outputting, for each detected object, the type of the object and the BBOX list.

22. The method according to claim 21, wherein the ODA is configured or trained for combining several of the identified sets of points for determining the type of object, the BBOX list being configured for listing the BBOXes whose associated set of points is part of the combination.

23. The method according to claim 16, further comprising, in addition to acquiring or receiving the point cloud, acquiring or receiving one or several images of the scene, and using the one or several images together with the point cloud as input to the ODA for detecting the one or several objects.

24. A method for providing, by a data processing system, a trained algorithm for detecting one or several objects in a point cloud that represents a scene and assigning to each detected object an object type chosen from a set of one or several predefined types and a list of bounding boxes (BBOX), the method comprising:
receiving input training data, the input training data including a plurality of point clouds, each representing a scene with one or several objects;
receiving output training data, the output training data identifying, for each of the point clouds of the input training data, at least one object of the scene, and for each identified object, associating with the at least one object a type of object chosen from the set of one or several predefined types and a list of BBOXes, wherein each BBOX of the BBOX list defines a spatial location within the point cloud including a set of points representing the object or a part of the object;
training an algorithm based on the input training data and the output training data to form a trained algorithm; and
providing the resulting trained algorithm.

25. The method according to claim 24, wherein the input training data includes a plurality of point clouds that each represent a different scene.

26. A data processing system comprising:
a processor; and
an accessible memory, the data processing system being configured to:
acquire or receive a point cloud representing a scene;
use an object detection algorithm for detecting, in the point cloud, one or several objects of the scene, the ODA being configured for outputting, for each detected object, an object type selected from a set of one or several predefined object types and a list of bounding boxes (BBOX), wherein each BBOX of the list is configured for defining a spatial location within the point cloud comprising a set of points representing the detected object or a part of the object;
for each of the predefined object types that was outputted, automatically create a first list of all BBOXes that have been outputted together with the predefined type;
for each BBOX outputted by the ODA, automatically create a second list of all predefined object types that have been outputted for a detected object whose associated BBOX list comprises the respective BBOX;
use at least one of the first or second lists for automatically filtering the point cloud.

27. The data processing system according to claim 26, wherein, upon a selection of a position within a displayed image created from the point cloud, the processor is configured to automatically determine to which BBOX the position belongs to, and to automatically display the second list of predefined object types listed for the respective BBOX.

28. The data processing system according to claim 26, wherein, upon a selection of one of the predefined object types of the second list of predefined object types, displaying or hiding only the points of the sets of points associated with the BBOXes of the first list created for the predefined object type that has been selected.

29. A non-transitory computer-readable medium encoded with executable instructions that, when executed, cause one or more data processing systems to:
acquire or receive a point cloud representing a scene comprising one or several objects;
use an object detection algorithm for detecting, in the point cloud, at least one object of the one or several objects of the scene, the ODA being configured for outputting, for each object detected in in the point cloud, an object type chosen from a set of one or several predefined object types and a list of bounding boxes (BBOX), wherein each BBOX of the list of BBOXes is configured for defining a spatial location within the point cloud comprising a set of points representing the detected object or a part of the detected object;
for each of the predefined object types that was outputted, automatically create a first list of all BBOXes that have been outputted together with the predefined type;
for each BBOX outputted by the ODA, automatically create a second list of all predefined object types that have been outputted for a detected object whose associated BBOX list includes the BBOX; and
use at least one of the first or second lists for automatically filtering the point cloud.

30. The non-transitory computer-readable medium according to claim 29, wherein, upon a selection of a position within a displayed image created from the point cloud, the one or more data processing systems are configured to automatically determine to which BBOX the position belongs, and to automatically display the second list of predefined object types listed for the respective BBOX.

31. The non-transitory computer-readable medium according to claim 29, wherein, upon a selection of one of the predefined object types of the second list of predefined object types, the one or more data processing systems are configured for automatically displaying or hiding only the points of the set or sets of points associated with the BBOXes of the first list created for the predefined object type that has been selected.
